(19) United States
(12) Patent Application Publication
(10) Pub. No.: US 2025/0358940 A1
(43) Pub. Date: Nov. 20, 2025

(54) QUICK-SPLICING STRUCTURE AND CABINET

(71) Applicant: Starcharge Energy Pte Ltd, Singapore (SG)

(72) Inventors: YU-MING CHANG, Singapore (SG); HSIEN-YI TSAI, Singapore (SG); TSUNG-YUAN WU, Singapore (SG)

(73) Assignee: Starcharge Energy Pte Ltd, Singapore (SG)

(21) Appl. No.: 18/668,226

(22) Filed: May 19, 2024

(51) Int. Cl. H05K 5/02

(52) U.S. Cl. CPC H05K 5/02

(57) ABSTRACT

The disclosure relates to the technical field of cabinet splicing and specifically relates to a quick-splicing structure and a cabinet. A quick-splicing structure for quick connection between two surfaces includes at least one group of slidably fitting components and a plurality of groups of locking components. The slidably fitting components include a first member and a second member that are slidably fitted and disposed on the two surfaces. The locking components include a first fastener and a second fastener that are fitted to be locked and respectively disposed on the two surfaces, and the plurality of groups of locking components and the slidably fitting components are arranged in an alternating manner in a locking direction. The disclosure further provides a cabinet including the quick-splicing structure. A plurality of the cabinets are connected horizontally and/or vertically through the quick-splicing structure.

### BACKGROUND

### Technical Field

The disclosure relates to the technical field of cabinet splicing and specifically relates to a quick-splicing structure and a cabinet.

### Description of Related Art

At present, in energy consumption application scenarios, such as charging piles, communication power supplies, energy storage systems, etc., the problems of these all-in-one equipment include heavy weight, difficulty in handling, inconvenient on-site installation, and poor scalability. Therefore, a modular installation solution is provided. In the solution, multiple cabinet installation modules are used for splicing, so the cabinets can be assembled on site, and the involvement of construction cranes, forklifts, and other professional tooling is minimized. These modular functional modules further facilitate the implementation of streamlined, specialized, and standardized production in the factory. Moreover, on-site replacement and on-site upgrades can be easily performed, so strong scalability is provided.

At present, the mainstream splicing solutions adopt the approach of splicing in the up and down directions. However, the up-down splicing approach requires guiding and positioning through pin-hole fitting and the like, so the guiding effect is poor, installation is difficult, and maintenance is inconvenient when the equipment fails.

### SUMMARY

In order to solve the technical problems of poor guiding effect and difficult installation found in pin-hole fitting during splicing of cabinets in the related art, the disclosure provides applicable cabinet to solve the above technical problems.

The technical solution adopted by the disclosure is provided as follows.

The disclosure provides a quick-splicing structure for quick connection between two surfaces, comprising:
At least one group of slidably fitting components, The least one group of slidably fitting components includes a first member and a second member that are slidably fitted and disposed on the two surfaces; and
a plurality of groups of locking components, the locking components include a first fastener and a second fastener that are fitted to be locked and respectively disposed on the two surfaces, and the plurality of groups of locking components and the slidably fitting components are arranged in an alternating manner in a locking direction.

According to an embodiment of the disclosure, the at least one group of slidably fitting components is sliding-rail-type slidably fitting components, and the at least one group of sliding-rail-type slidably fitting components is extended in the locking direction.

According to an embodiment of the disclosure, the plurality of groups of locking components are dispersedly arranged in locking positions between the two surfaces, and the two groups of locking components located in the locking direction are misaligned.

According to an embodiment of the disclosure, the at least one group of slidably fitting components is two groups, and the two groups of slidably fitting components are symmetrical with respect to center lines of the surfaces.

Alternatively, the at least one group of slidably fitting components is one group, and the one group of slidably fitting components is located on the center line of the surface.

Alternatively, the at least one group of slidably fitting components is one group, and further including at least one pulley, the at least one pulley is disposed on any one of the two surfaces, and the slidably fitting components and the at least one pulley are symmetrical with respect to the center line of the surface.

According to an embodiment of the disclosure, the first fastener and the second fastener are both L-shaped locking members. The first fastener and the second fastener are provided with holes in the locking direction, and the holes on the first fastener and the second fastener are locked and connected through the locking members.

The disclosure further provides a cabinet including the quick-splicing structure. A plurality of the cabinets are connected horizontally and/or vertically through the quick-splicing structure.

According to an embodiment of the disclosure, the slidably fitting components vertically located on the two surfaces are configured as V-shaped sliding-rail fitting components.

According to an embodiment of the disclosure, the slidably fitting components horizontally located on the two surfaces are configured as dovetail sliding-rail fitting components.

Based on the foregoing technical solution, the technical effects produced by the disclosure include the following.

1. In the quick-splicing structure provided by the disclosure, through the arrangement of the slidably fitting components and the locking components and the misalignment of the locking components and the slidably fitting components in the locking direction, the interference problem found in alignment is solved. In this way, when the two surfaces are to be connected, the two surfaces may be misaligned, and rapid initial positioning is achieved through the sliding-rail-type slidably fitting components after the second surface is roughly in place. The second surface then slides in an X-axis direction until the first fastener contacts the second fastener, so positioning is achieved. The first fastener and the second fastener are then locked, and the splicing is completed. The entire splicing process requires significantly less positioning and is fast and convenient, and the splicing stability is further improved through the slidably fitting components.

2. Regarding the cabinet provided by the disclosure, a plurality of the cabinets can be spliced vertically through the arrangement of the vertical splicing components and can be spliced horizontally through arrangement of the horizontal splicing components. Both vertical splicing components and horizontal splicing components can adopt the quick-splicing structure, so that cabinets can be spliced together in both horizontal and vertical directions. Further, both the vertical splicing components and the horizontal splicing components are the sliding groove and sliding rail structure, so the cabinets can only slide along the sliding rails once they are docked. That is, the sliding rails can can also be used for guiding, so that there is no deviation in the direction of movement when the cabinets are spliced together.

3. In the cabinet provided by the disclosure, the first sliding rail in the vertical splicing components is located on the upper surface of the cabinet body, and a horizontal width gradually increases from top to bottom. In this way, when vertical splicing is to be performed, even if the upper first sliding groove and the lower first sliding rail are misaligned, due to the effect of gravity, the upper first sliding groove slides down the lower first sliding rail until the first sliding rail and the first sliding groove are fully fitted. In this way, the first sliding rail has good guiding properties. The first sliding rail is further configured to be in an inverted V shape, and the first sliding groove is adapted to the shape of the first sliding rail. In this way, when the upper cabinet and the lower cabinet are misaligned, the inverted V-shaped first sliding rail can be guided to an appropriate position, and then the upper cabinet can be pushed along the first sliding rail to achieve vertical splicing of the cabinets. Further, due to the limitation of the shape of the first sliding rail, the upper cabinet does not need to be dropped from the end of the first sliding rail to be spliced with the lower cabinet. The upper cabinet can be dropped from the non-end position of the first sliding rail to be spliced with the lower cabinet. In this way, the path for vertical splicing between cabinets is reduced, the difficulty of vertical splicing is reduced, and the splicing efficiency is improved.

4. In the cabinet provide by the disclosure, at least two groups of vertical splicing components are provided and are disposed in parallel. In this way, the upper cabinet can slide smoothly along the lower cabinet to be spliced without tilting. One group of vertical splicing components can further be arranged, and pulleys can be added for support to ensure stability.

5. In the cabinet provided by the disclosure, a vertical splicing limiting component is further arranged. When the upper limiting member abuts the lower limiting member, it can be determined that the vertical splicing is in place, and then the locking member is used to lock the upper limiting member and the lower limiting member to achieve fixing between the cabinets. Further, an upper limiting member is provided at each corner of the upper surface of the cabinet body. Moreover, the upper limiting member located at one end of the vertical splicing component is biased inward relative to the upper limiting member located at the other end of the vertical splicing component. In this way, during vertical splicing, interference between the lower limiting member and the upper limiting member can be prevented from being generated, and it is ensured that each lower limiting member can be pressed against the corresponding upper limiting member and then locked by the locking member.

6. In the cabinet provided by the disclosure, the second sliding rail extends horizontally, and anti-separation grooves are formed on the upper and lower side surfaces. In this way, when the cabinets are horizontally spliced together, the second sliding rail can act as a sliding guide and can also prevent separation between cabinets.

7. In the cabinet provided by the disclosure, a horizontal splicing limiting component is further arranged. When the left limiting member correspondingly abuts the right limiting member, it can be determined that the horizontal splicing is in place, and the locking member is then used to lock the left limiting member and the right limiting member to achieve fixing between the cabinets. Further, a left limiting member is provided at each corner of the left surface of the cabinet body. The left limiting member located at one end of the horizontal splicing limiting component is biased inward relative to the left limiting member located at the other end of the horizontal splicing limiting component. In this way, during horizontal splicing, interference between the right limiting member and the left limiting member can be prevented from being generated, and it is ensured that each left limiting member can be pressed against the corresponding right limiting member and then locked by the locking member.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic structural view of a quick-splicing structure in Embodiment One of the disclosure.

FIG. 2 is a schematic structural view of a cabinet in Embodiment Two of the disclosure.

FIG. 3 is a state view of cabinets being vertically spliced.

FIG. 4 is a schematic view of fitting between vertical splicing components when the cabinets are vertically spliced.

FIG. 5 is a state view of the cabinets being horizontally spliced.

FIG. 6 is a front view of the two cabinets after they are horizontally spliced.

FIG. 7 is an enlargement view of a portion A of FIG. 6.

FIG. 8 is a state view of a plurality of cabinets being horizontally and vertically spliced.

FIG. 9 is a top view of the structure shown in FIG. 7.

FIG. 10 is a left side view of the structure shown in FIG. 7.

In the drawings, a—first surface, b—second surface, 1a—first member, 1b—second member, 2a—first fastener, 2b—second fastener, 1—cabinet body, 11—cabinet door, 12—cable hole, 2—vertical splicing component, 21—first sliding rail, 22—first sliding groove, 3—horizontal splicing component, 31—second sliding rail, 311—anti-separation groove, 32—second sliding groove, 4—vertical splicing limiting component, 41—upper limiting member, 42—lower limiting member, 5—horizontal splicing limiting component, 51—left limiting member, 52—right limiting member, and 6—locking member.

### DESCRIPTION OF THE EMBODIMENTS

The technical solutions in the embodiments of the disclosure will be clearly and completely described below with reference to the accompanying drawings in the embodiments of the disclosure. Obviously, the described embodiments are only a part of the embodiments of the disclosure, but not all of the embodiments. Based on the embodiments of the disclosure, all other embodiments obtained by a person having ordinary skill in the art without any creative effort fall within the protection scope of the disclosure.

### Embodiment One

In the related art, there are many objects, such as electrical cabinets, server cabinets, computer cases, etc., that need to be spliced together. When splicing is performed, two surfaces are usually required to be quickly spliced and locked, so precise positioning is needed during the connection process. Electrical cabinets, etc. are heavy and usually need to be hoisted and aligned. During the splicing process, the position of electrical cabinets must be adjusted in real time to ensure that the two surfaces are in the same direction, which is time-consuming and labor-intensive. For this reason, this embodiment provides a quick-splicing structure for quick connection between two surfaces.

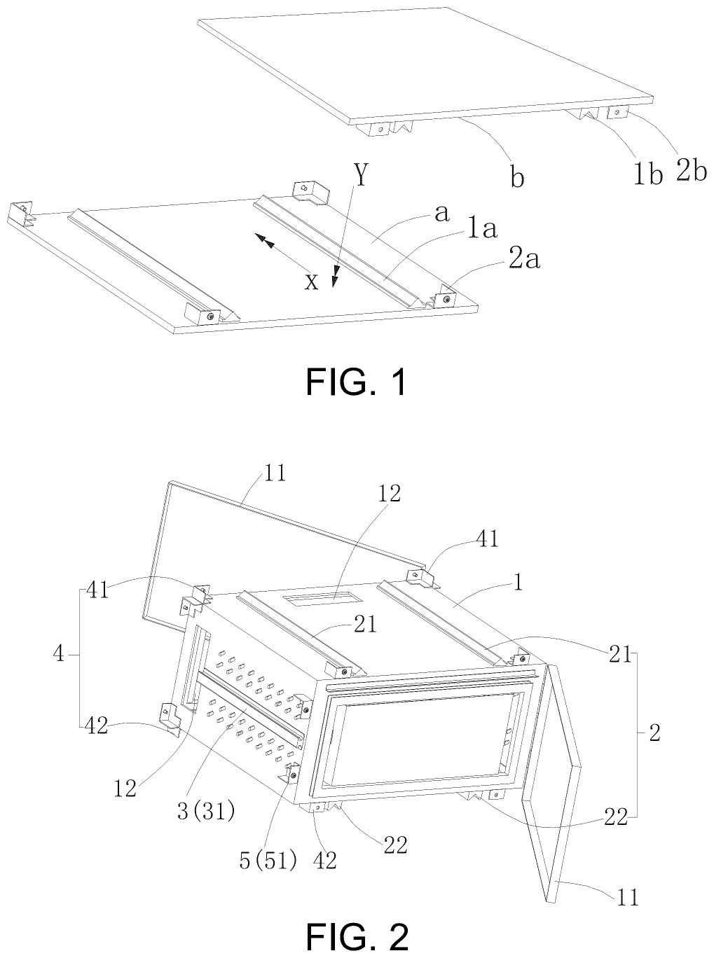

As shown in FIG. 1, the two surfaces to be connected are a first surface a and a second surface b. The quick-splicing structure includes at least one group of slidably fitting components and a plurality of groups of locking components. The slidably fitting components include a first member 1a and a second member 1b that are slidably fitted and respectively disposed on two surfaces. Preferably, the slidably fitting components are sliding-rail-type slidably fitting components, and the sliding-rail-type slidably fitting components extend in a locking direction. Further, the locking components include a first fastener 2a and a second fastener 2b that are fitted to be locked and respectively disposed on the two surfaces, and the plurality of groups of locking components and the slidably fitting components are arranged in an alternating manner in the locking direction. Due to the misalignment arrangement, the interference problem found in alignment is solved. In this way, when the first surface a and the second surface b are to be connected, the two surfaces may be misaligned, and rapid initial positioning is achieved through the sliding-rail-type slidably fitting components after the second surface b is roughly in place. The second surface b then slides in an X-axis direction until the first fastener 2a contacts the second fastener 2b, so positioning is achieved. The first fastener 2a and the second fastener 2b are then locked, and the splicing is completed. The entire splicing process requires significantly less positioning and is fast and convenient, and the splicing stability may be further improved through the slidably fitting components.

As a preferred technical solution of this embodiment, both surfaces are square surfaces, the locking components are preferably in four groups, and the four groups of locking components are arranged at the four corners of the square surfaces. The plurality of groups of locking components are dispersedly arranged in locking positions between the two surfaces, and the two groups of locking components located in the locking direction are misaligned. In this way, the interference problem between the locking components can be solved. When the first surface a and the second surface b are to be connected, the two surfaces may be completely misaligned, the docking starts from one end of the surface, and then sliding and splicing are performed.

Further, the at least one group of slidably fitting components is preferably two groups, and the two groups of slidably fitting components are symmetrical with respect to center lines of the square surfaces. In this way, once the two groups of slidably fitting component are in contact, it is ensured that the two surfaces are parallel to each other and initial positioning is achieved. The second surface b is then slid and quick splicing is thus achieved.

As a preferred technical solution of this embodiment, the at least one group of slidably fitting components is one group, and the one group of slidably fitting components is located on the center line of the surface. In this way, the slidably fitting component may be saved, and quick splicing may also be achieved.

As a preferred technical solution of this embodiment, the at least one group of slidably fitting components is one group, and the quick-splicing structure further includes a pulley. The pulley is disposed on any surface between the two surfaces, and the slidably fitting components and the pulley are symmetrical with respect to the center line of the surface. In this way, once the two groups of slidably fitting component are in contact, it is ensured that the two surfaces are parallel to each other and initial positioning is achieved. The second surface is then slid and quick splicing is thus achieved.

As a preferred technical solution of this embodiment, the first fastener 2a and the second fastener 2b are both L-shaped locking members. The first fastener 2a and the second fastener 2b are provided with threaded holes in the locking direction, and the holes on the first fastener 2a and the second fastener 2b are locked and connected through screws.

### Embodiment Two

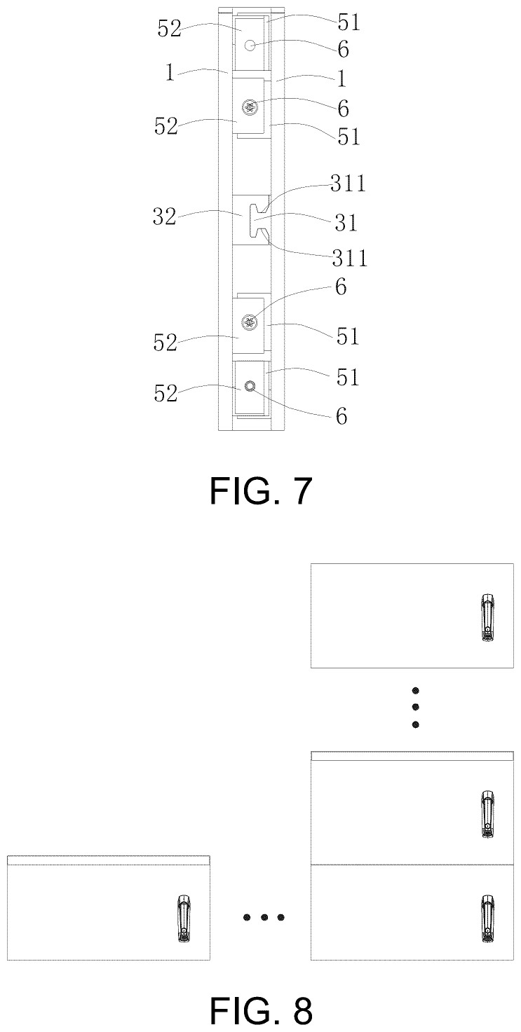

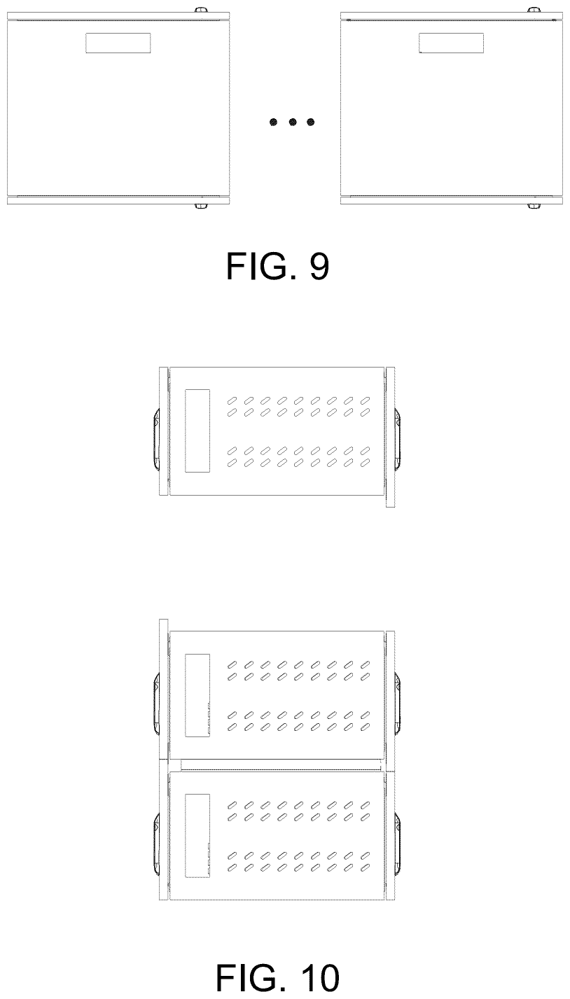

As shown in FIG. 2 to FIG. 10, this embodiment provides a cabinet including a cabinet body 1. A plurality of cabinet bodies 1 are spliced together using the quick-splicing structure in Embodiment One. Upper and lower surfaces of each cabinet body 1 are provided with vertical splicing components 2, and left and right surfaces of each cabinet body 1 are provided with horizontal splicing components 3. The cabinets may be spliced vertically through the vertical splicing components 2 and may be spliced horizontally through the horizontal splicing components 3.

Each cabinet body 1 is in the shape of a square cabinet, and a front end and/or a rear end of the cabinet body 1 may be provided with cabinet door(s) 11 as needed. An accommodating space is provided inside the cabinet body 1 to accommodate a module, and a cable hole 12 is formed on a side surface of the cabinet body 1. When the modules in multiple cabinet bodies 1 need to be electrically connected through cables, the cables may pass through the cable holes 12 to electrically connect the modules.

As a preferred technical solution of this embodiment, except for the surface where the cabinet door 11 is located, all other surfaces of the cabinet body 1 may be provided with the cable holes 12 to facilitate the passing of the cables. In this embodiment, the cabinet doors 11 are provided at both the front and rear ends of the cabinet body 1, and the cable holes 12 are formed on the upper and lower surfaces and the left and right surfaces of the cabinet body 1.

At least one group of vertical splicing components 2 is provided, and the vertical splicing components 2 in this embodiment adopt the quick-splicing structure in Embodiment One. Herein, the first member 1a is configured as a first sliding rail 21, the second member 1b is configured as a first sliding groove 22, and the first sliding rail 21 and the first sliding groove 22 are located on the upper surface and the lower surface of the cabinet body 1 respectively.

As a preferred technical solution of this embodiment, two groups of vertical splicing components 2 are provided, and the two groups of vertical splicing components 2 are arranged in parallel and spaced apart. The two first sliding rails 21 are parallel and symmetrically distributed on the upper surface of the cabinet body 1, and the first sliding rails 21 extend in front and rear directions of the cabinet body 1. The cable hole 12 disposed on the upper surface of the cabinet body 1 is located between the two first sliding rails 21, and the cable hole 12 disposed on the lower surface of the cabinet body 1 may be located between the two first sliding grooves 22.

As a preferred technical solution of this embodiment, the first sliding rail 21 is located on the upper surface of the cabinet body 1, and a horizontal width of the first sliding rail 21 gradually increases from top to bottom. The first sliding groove 22 is located on the lower surface of the cabinet body 1, and a shape of the first sliding groove 22 is adapted to a shape of the first sliding rail 21. Preferably, each vertical splicing component 2 is a V-shaped sliding-rail fitting component. Specifically, the first sliding rail 21 is configured to have an inverted V shape, and correspondingly, the first sliding groove 22 is an inverted V-shaped sliding groove.

As a preferred technical solution of this embodiment, an extension length of the first sliding groove 22 is consistent with an extension length of the first sliding rail 21.

In order to limit the cabinet that is assembled in place, the cabinet body 1 is also provided with a vertical splicing limiting component 4 adopting the locking component in Embodiment One. The first fastener 2a is configured as an upper limiting member 41, and the second fastener 2b is configured as a lower limiting member 42. When splicing, the upper cabinet falls to the lower cabinet. Since the first sliding rail 21 is in an inverted V shape, the first sliding groove 22 of the upper cabinet may be automatically aligned with the first sliding rail 21 of the lower cabinet under the action of gravity, and then the upper cabinet may be pushed to slide on the lower cabinet. When the lower limiting member 42 of the upper cabinet is blocked by the upper limiting member of the lower cabinet, a locking member 6 is used to lock the corresponding upper limiting member 41 and lower limiting member 42, and the upper cabinet is then assembled in place.

As a preferred technical solution of this embodiment, an upper limiting member 41 is provided at each corner of the upper surface of the cabinet body 1, and the upper limiting members 41 are symmetrically distributed on both outer sides of the two first sliding rails 21.

As a preferred technical solution of this embodiment, in order to avoid interference, the upper limiting member 41 located at one end of the first sliding rail 21 is biased inward relative to the upper limiting member 41 located at the other end of the first sliding rail 21, so that the upper limiting members 41 are misaligned, and interference is thus avoided.

As a preferred technical solution of this embodiment, the number of lower limiting members 42 on the lower surface of the cabinet body 1 is consistent with the number of upper limiting members 41, and their positions are set correspondingly. During vertical splicing, the lower limiting members 42 of the upper cabinet may be pressed one by one with the upper limiting members 41 of the lower cabinet, and the locking members 6 may be fixed one by one.

As a preferred technical solution of this embodiment, each upper limiting member 41 and each lower limiting member 42 may be installation angles for supporting and limiting. The upper limiting member 41 and the lower limiting member 42 are provided with holes in the locking direction, and the locking member 6 passes through the holes in the upper limiting member 41 and the lower limiting member 42 for locking. The locking member 6 may be a screw.

At least one group of horizontal splicing components 3 is provided, and the horizontal splicing components 3 also adopt the quick-splicing structure in Embodiment One. Herein, the first member 1a is configured as a second sliding rail 31, the second member 1b is configured as a second sliding groove 32, and the second sliding rail 31 and the second sliding groove 32 are located on the left surface and the right surface of the cabinet body 1 respectively.

As a preferred technical solution of this embodiment, one group of horizontal splicing components 3 is provided, and the horizontal splicing components 3 may be located at a middle position of a height of the cabinet body 1 and extend horizontally. During splicing, the cabinets slide and splice horizontally.

As a preferred technical solution of this embodiment, the second sliding rail 31 is located on the left surface of the cabinet body 1, and the second sliding groove 32 is located on the right surface of the cabinet body 1, and vice versa.

As a preferred technical solution of this embodiment, the second sliding rail 31 extends horizontally, and anti-separation grooves 311 are formed on the upper and lower side surfaces of the second sliding rail 31. When the second sliding groove 32 and the second sliding rail 31 are slidably fitted, the two horizontally spliced cabinets do not separate. Preferably, each vertical splicing component 3 is a dovetail sliding-rail fitting component. To be specific, the anti-separation grooves 311 formed on the upper and lower side surfaces of the second sliding rail 31 are dovetail grooves.

In order to limit the cabinet that is horizontally spliced in place, the cabinet body 1 is also provided with a horizontal splicing limiting component 5 adopting the splicing structure in Embodiment One as well. Herein, the first fastener 2a is configured as a left limiting member 51, and the second fastener 2b is configured as a right limiting member 52. Positions of the left limiting member 51 and the right limiting member 52 correspond to each other. For instance, when a cabinet is to be spliced from the left, the left cabinet approaches from the left side of the right cabinet. The second sliding groove 32 of the left cabinet may slide and dock with the second sliding rail 31 from the front end of the right cabinet, and then the left cabinet may be pushed to slide relative to the right cabinet. When the right limiting member 52 of the left cabinet is blocked by the left limiting member of the right cabinet, the locking member 6 is used to lock the corresponding left limiting member 51 and right limiting member 52, and the left cabinet is then assembled in place.

As a preferred technical solution of this embodiment, a left limiting member 51 is provided at each corner of the left surface of the cabinet body 1, and the left limiting members 51 are symmetrically distributed on both sides of the second sliding rail 21.

As a preferred technical solution of this embodiment, in order to avoid interference, the left limiting member 51 located at one end of the second sliding rail 21 is biased inward relative to the left limiting member 51 located at the other end of the second sliding rail 21, so that the left limiting members 51 are misaligned in a height direction, and interference is thus avoided.

As a preferred technical solution of this embodiment, the number of right limiting members 52 on the right surface of the cabinet body 1 is consistent with the number of left limiting members 51, and their positions are set correspondingly. During horizontal splicing, the right limiting members 52 of the left cabinet may be pressed one by one with the left limiting members 51 of the right cabinet, and the locking members 6 may be fixed one by one.

As a preferred technical solution of this embodiment, each left limiting member 51 and each right limiting member 52 may be installation angles. The left limiting member 51 and the right limiting member 52 are provided with holes in the locking direction, and the locking member 6 passes through the holes in the left limiting member 51 and the right limiting member 52 for locking.

Based on the above technical solution, the splicing solution of the applicable cabinet in this embodiment is:

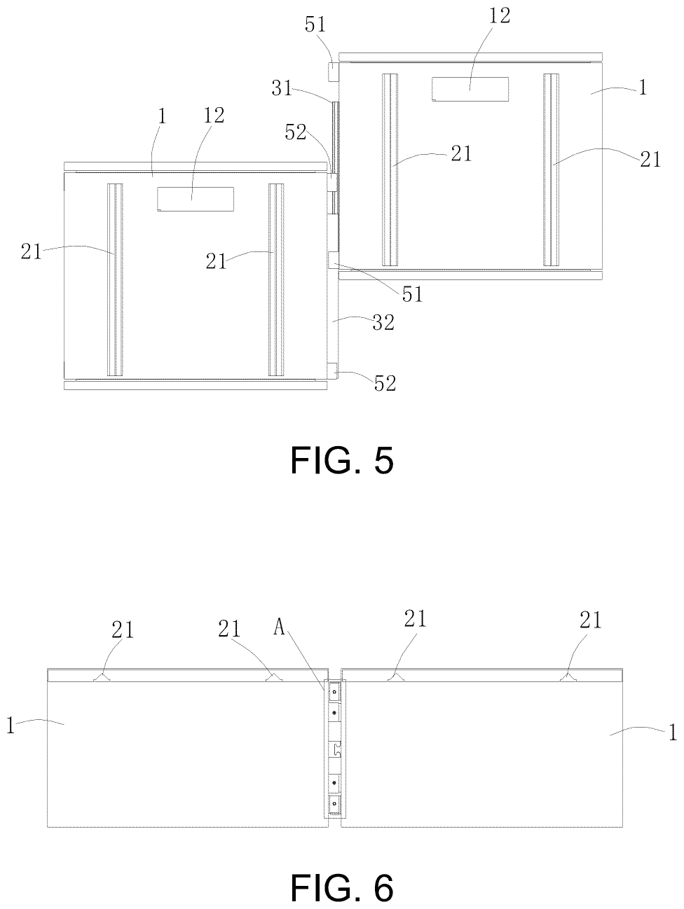

Horizontal splicing: The module may be installed into the cabinet body 1 before splicing, for example, the module may be installed into a drawer cabinet inside the cabinet body 1. The front and rear cabinet doors 11 are closed. The left cabinet is guided by the second sliding rail 21 of the cabinet and pushed from front to back along the second sliding rail, as shown in FIG. 5, until the right limiting member 52 of the left cabinet and the left limiting member 51 of the right cabinet resist the limit. The locking member 6 is then used for locking, as shown in FIG. 6.

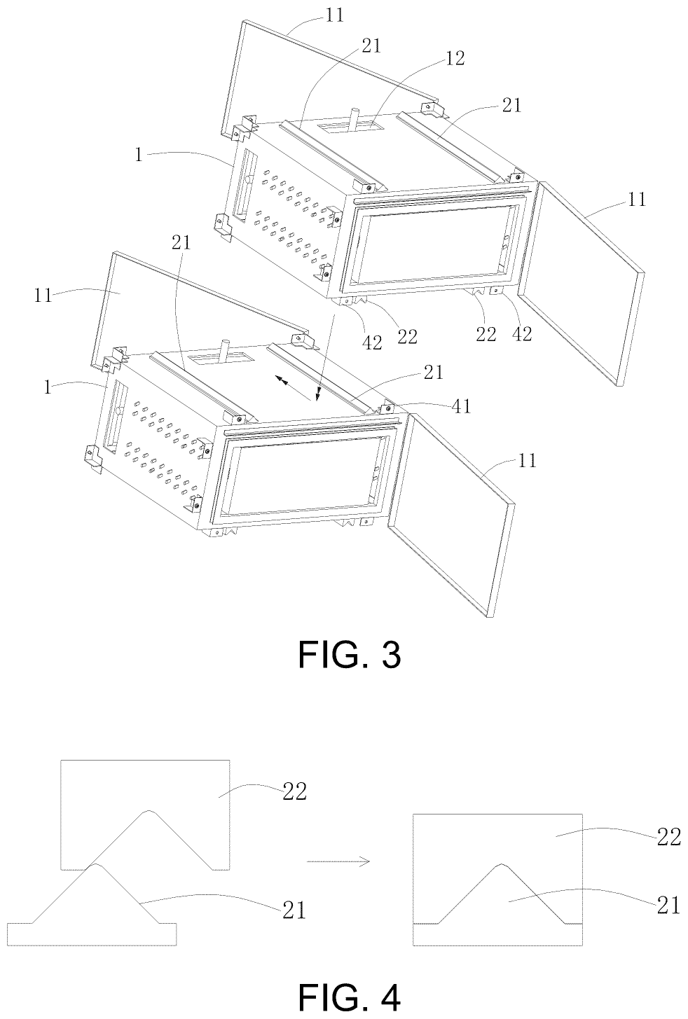

Vertical splicing: The module may be installed into the cabinet body 1 before splicing, for example, the module may be installed into the drawer cabinet inside the cabinet body 1. The front and rear cabinet doors 11 are open, and the bottom cabinet has been fixed on the foundation. The upper cabinet is misaligned and fitted to the lower cabinet downward. The upper cabinet is guided to the appropriate position by the inverted V shape of the first sliding rail 21, as shown in FIG. 4, and then the upper cabinet is pushed from front to back along the direction of the first sliding rail 21, as shown in FIG. 3, until the lower limiting member 42 of the upper cabinet and the upper limiting member 41 of the lower cabinet resist the limit. The locking member 6 is then used for locking, and the front cabinet door 11 is then closed.

Final assembly wiring: After all the cabinets are spliced, the cabinet doors 11 at the back are opened together. The wiring is carried out through the four cable holes 12 opened on the cabinet body 1 to transmit electronic and electrical signals between the various modules. Finally, the cabinet doors 11 are locked to complete the installation of the entire equipment, and the effect is shown in FIG. 8 to FIG. 10.

### Embodiment Three

This embodiment is basically the same as Embodiment Two, and the difference is that there is only one group of vertical splicing components 2, and pulleys are added on the other side to ensure a mirrored distribution of the support points of a single cabinet, which facilitates horizontal placement and ensures stability after the upper and lower cabinets are spliced.

The pulleys may be disposed on the upper surface and/or lower surface of the cabinet body 1, and when both the upper surface and the lower surface of the cabinet body 1 are equipped with the pulleys, the pulleys need to be misaligned.

In the disclosure, unless clearly specified and defined otherwise, the terms “installed”, “connected”, “connecting”, “fixed” and other terms should be understood in a broad sense, for instance, it can be a fixed connection, a detachable connection, or an integral connection, it can be a mechanical connection or an electrical connection, it can be a direct connection or an indirect connection through an intermediate medium, and it can be an internal communication between two modules or an interaction relationship between two modules.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A quick-splicing structure for quick connection between two surfaces, comprising:
at least one group of slidably fitting components, wherein the slidably fitting components comprise a first member and a second member that are slidably fitted and respectively disposed on the two surfaces; and
a plurality of groups of locking components, wherein the locking components comprise a first fastener and a second fastener that are fitted to be locked and respectively disposed on the two surfaces, and the plurality of groups of locking components and the slidably fitting components are arranged in an alternating manner in a locking direction.

2. The quick-splicing structure according to claim 1, wherein the at least one group of slidably fitting components is sliding-rail-type slidably fitting components, and the at least one group of sliding-rail-type slidably fitting components is extended in the locking direction.

3. The quick-splicing structure according to claim 1, wherein the plurality of groups of locking components are dispersedly arranged in locking positions between the two surfaces, and the two groups of locking components located in the locking direction are misaligned.

4. The quick-splicing structure according to claim 1, wherein the at least one group of slidably fitting components is two groups, and the two groups of slidably fitting components are symmetrical with respect to center lines of the surfaces,
the at least one group of slidably fitting components is one group, and the one group of slidably fitting components is located on the center line of the surface, or
the at least one group of slidably fitting components is one group, and further comprising at least one pulley, the at least one pulley is disposed on any one of the two surfaces, and the slidably fitting components and the at least one pulley are symmetrical with respect to the center line of the surface.

5. The quick-splicing structure according to claim 1, wherein the first fastener and the second fastener are both L-shaped locking members, the first fastener and the second fastener are provided with holes in the locking direction, and the holes on the first fastener and the second fastener are locked and connected through the locking members.

6. A cabinet comprising the quick-splicing structure according to claim 1, wherein a plurality of the cabinets are connected horizontally and/or vertically through the quick-splicing structure.

7. The cabinet according to claim 6, wherein the slidably fitting components vertically located on the two surfaces are configured as V-shaped sliding-rail fitting components.

8. The cabinet according to claim 7, wherein the slidably fitting components horizontally located on the two surfaces are configured as dovetail sliding-rail fitting components.

9. The quick-splicing structure according to claim 2, wherein the at least one group of slidably fitting components is two groups, and the two groups of slidably fitting components are symmetrical with respect to center lines of the surfaces,
the at least one group of slidably fitting components is one group, and the one group of slidably fitting components is located on the center line of the surface, or
the at least one group of slidably fitting components is one group, and further comprising at least one pulley, the at least one pulley is disposed on any one of the two surfaces, and the slidably fitting components and the at least one pulley are symmetrical with respect to the center line of the surface.

10. The quick-splicing structure according to claim 3, wherein the at least one group of slidably fitting components is two groups, and the two groups of slidably fitting components are symmetrical with respect to center lines of the surfaces,
the at least one group of slidably fitting components is one group, and the one group of slidably fitting components is located on the center line of the surface, or
the at least one group of slidably fitting components is one group, and further comprising at least one pulley, the at least one pulley is disposed on any one of the two surfaces, and the slidably fitting components and the at least one pulley are symmetrical with respect to the center line of the surface.

11. A cabinet comprising the quick-splicing structure according to claim 2, wherein a plurality of the cabinets are connected horizontally and/or vertically through the quick-splicing structure.

12. A cabinet comprising the quick-splicing structure according to claim 3, wherein a plurality of the cabinets are connected horizontally and/or vertically through the quick-splicing structure.

13. A cabinet comprising the quick-splicing structure according to claim 4, wherein a plurality of the cabinets are connected horizontally and/or vertically through the quick-splicing structure.

14. A cabinet comprising the quick-splicing structure according to claim 5, wherein a plurality of the cabinets are connected horizontally and/or vertically through the quick-splicing structure.

15. The cabinet according to claim 11, wherein the slidably fitting components vertically located on the two surfaces are configured as V-shaped sliding-rail fitting components.

16. The cabinet according to claim 12, wherein the slidably fitting components vertically located on the two surfaces are configured as V-shaped sliding-rail fitting components.

17. The cabinet according to claim 13, wherein the slidably fitting components vertically located on the two surfaces are configured as V-shaped sliding-rail fitting components.

18. The cabinet according to claim 15, wherein the slidably fitting components horizontally located on the two surfaces are configured as dovetail sliding-rail fitting components.

19. The cabinet according to claim 16, wherein the slidably fitting components horizontally located on the two surfaces are configured as dovetail sliding-rail fitting components.

20. The cabinet according to claim 17, wherein the slidably fitting components horizontally located on the two surfaces are configured as dovetail sliding-rail fitting components.
